(19) United States
(12) Patent Application Publication
(10) Pub. No.: US 2025/0279303 A1
(43) Pub. Date: Sep. 4, 2025

(54) METHOD OF MANUFACTURING SEMICONDUCTOR DEVICE

(71) Applicant: Mitsubishi Electric Corporation, Tokyo (JP)

(72) Inventors: Kazuaki MIKAMI, Tokyo (JP); Shotaro NAKAMURA, Tokyo (JP); Tsuyoshi TSUCHIYA, Tokyo (JP); Satoshi YASUI, Tokyo (JP); Yasuo KONISHI, Tokyo (JP)

(73) Assignee: Mitsubishi Electric Corporation, Tokyo (JP)

(21) Appl. No.: 18/991,288

(22) Filed: Dec. 20, 2024

(30) Foreign Application Priority Data
Mar. 1, 2024 (JP) 2024-030897

(51) Int. Cl. H01L 21/673; H01L 21/265

(52) U.S. Cl. CPC H01L 21/67383; H01L 21/26506

(57) ABSTRACT

A method of manufacturing a semiconductor device includes a step of performing processing and a step of transporting. In the step of performing processing, processing for forming a semiconductor element is performed on a semiconductor substrate made from silicon carbide and having a diameter W of 200 mm or more. In the step of transporting, at least one of before and after processing, a semiconductor substrate is accommodated and transported in a FOUP, which is a transport carrier capable of accommodating a maximum of 25 semiconductor substrates.

### BACKGROUND OF THE INVENTION

### Field of the Invention

The present disclosure relates to a method of manufacturing a semiconductor device.

### Description of the Background Art

Switching to a semiconductor device made from silicon carbide (SiC), which has a lower loss than a semiconductor device made from silicon (Si) and can be expected to have higher reliability, is in progress. A semiconductor device made from Si is manufactured from a Si semiconductor substrate, and a semiconductor device made from SiC is manufactured from a SiC semiconductor substrate. A Si semiconductor substrate and a SiC semiconductor substrate are transported between processing apparatuses in a state of being accommodated in a transport carrier (also referred to as a transport container), and different processing is performed for each processing apparatus, so that a semiconductor element is formed on a semiconductor substrate (see, for example, Japanese Patent Application Laid-Open No. 2012-142620).

A SiC semiconductor substrate is different from a Si semiconductor substrate in not only a material but also a shape such as thickness in some cases, and a deformation amount of deflection such as warpage due to a weight of a SiC semiconductor substrate may be larger than a deformation amount of a Si semiconductor substrate. Further, a deformation amount becomes significant in a SiC semiconductor substrate having a diameter of 200 mm or more. For this reason, when a plurality of SiC semiconductor substrates having a diameter of 200 mm or more are transported in a state of being accommodated in a transport carrier, adjacent SiC semiconductor substrates may come into contact with each other during transportation, and a defect may occur.

On the other hand, in a conventional technique, a standard mechanical interface (SMIF) is used as a transport carrier that accommodates and transports a SiC semiconductor substrate. However, in an SMIF, since a housing for accommodating a SiC semiconductor substrate is small and a distance between accommodated SiC semiconductor substrates is short, there has been a problem that 25 semiconductor substrates cannot be transported as one unit due to the above-described defect, and manufacturability is poor.

### SUMMARY

The present disclosure has been made in view of the above problem, and an object of the present disclosure is to provide a technique capable of appropriately transporting a semiconductor substrate.

A method of manufacturing a semiconductor device according to the present disclosure includes a step of preparing a semiconductor substrate made from silicon carbide and having a diameter W of 200 mm or more, a step of performing processing for forming a semiconductor element on the semiconductor substrate, and a step of accommodating and transporting the semiconductor substrate in a FOUP that is a transport carrier capable of accommodating a maximum of 25 of the semiconductor substrates at least one of before and after the processing.

The semiconductor substrate can be appropriately transported.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view illustrating a configuration of a FOUP used in a method of manufacturing a semiconductor device according to a first preferred embodiment;

FIG. 2 is a cross-sectional view illustrating a configuration of a part of a FOUP used in the method of manufacturing a semiconductor device according to the first preferred embodiment;

FIGS. 3 and 4 are top views each illustrating a configuration of a FOUP used in the method of manufacturing the semiconductor device according to the first preferred embodiment.

FIGS. 5 and 6 are flowcharts each showing the method of manufacturing a semiconductor device according to the first preferred embodiment;

FIG. 7 is a cross-sectional view illustrating the method of manufacturing of a semiconductor device according to the first preferred embodiment;

FIGS. 8 and 9 are two-dimensional maps each showing a deflection amount of a semiconductor substrate of a semiconductor device according to the first preferred embodiment;

FIG. 10 is a diagram illustrating a relationship between angles of an upper support point and a lower support point and a maximum deflection amount of a semiconductor substrate accommodated in an FOUP according to the first preferred embodiment;

FIG. 11 is a cross-sectional view illustrating a part of a configuration of a FOUP used in the method of manufacturing a semiconductor device according to a second preferred embodiment;

FIG. 12 is a cross-sectional view illustrating a part of a configuration of an FOUP used in the method of manufacturing a semiconductor device according to a third preferred embodiment; and

FIG. 13 is a cross-sectional view illustrating a part of a configuration of a FOUP used in the method of manufacturing a semiconductor device according to a fourth preferred embodiment.

### DESCRIPTION OF THE PREFERRED EMBODIMENTS

Hereinafter, a preferred embodiment will be described with reference to the attached drawings. Features described in the following preferred embodiments are examples, and all features are not necessarily essential. Further, in description below, similar constituent elements in a plurality of preferred embodiments are denoted by the same or similar reference numerals, and a different constituent element will be mainly described. Further, in description below, specific positions and directions such as “upper”, “lower”, “left”, and “right” do not need to coincide with actual positions and directions in practice.

### First Preferred Embodiment

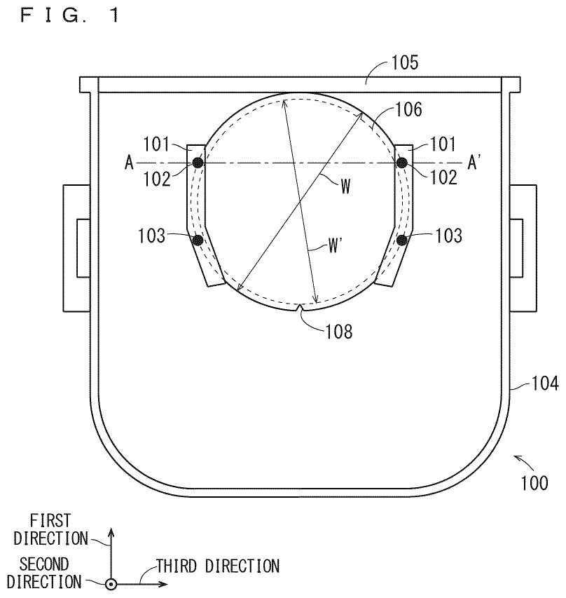

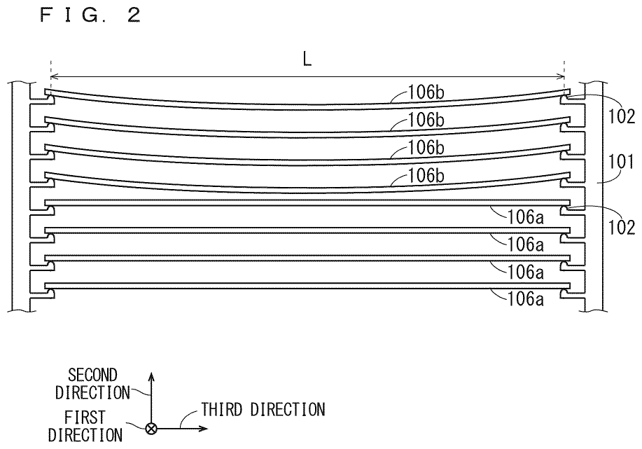

In a method of manufacturing a semiconductor device according to a first preferred embodiment, a front opening unified pod (FOUP) is used as a transport carrier that accommodates and transports a SiC semiconductor substrate. FIG. 1 is a top view illustrating a configuration of a FOUP 100 used in the method of manufacturing a semiconductor device according to the first preferred embodiment, and FIG. 2 is a cross-sectional view taken along line A-A′ of FIG. 1.

A semiconductor substrate 106 accommodated and transported in the FOUP 100 has a diameter W of 200 mm (8 inches) or more and is made from SiC (silicon carbide). Note that the semiconductor substrate 106 may include a wide band gap semiconductor other than SiC, such as gallium nitride (GaN), gallium oxide (Ga₂O₃), or diamond. In a in semiconductor device formed of the semiconductor substrate 106 of a wide band gap semiconductor, stable operation under temperature and high voltage, and high switching speed can be achieved. Hereinafter, a case where the diameter W of the semiconductor substrate 106 is 200 mm will be mainly described. If the semiconductor substrate 106 is a 12-inch semiconductor substrate, the diameter W may be read as 300 mm. Note that the diameter W indicates a dimension when a semiconductor substrate manufacturer manufactures and ships a semiconductor substrate.

The semiconductor substrate 106 includes, for example, at least one of a normal semiconductor wafer and an epitaxial growth layer. Note that in the present description, for example, at least one of A, B, C, . . . , and Z means any one of all combinations obtained by extracting one or more types from groups of A, B, C, . . . , and Z. As illustrated in FIG. 2, the semiconductor substrate 106 according to the first preferred embodiment may be a semiconductor substrate 106a having a small deflection amount or a semiconductor substrate 106b having a large deflection amount.

The FOUP 100 is a transport carrier capable of accommodating a maximum of 25 of the semiconductor substrates 106. As illustrated in FIGS. 1 and 2, the FOUP 100 includes a partition portion 101, an upper support point 102, a lower support point 103, a housing 104, and a lid 105. Note that in description below, in a case where the upper support point 102 and the lower support point 103 are not distinguished from each other, these may be collectively referred to as a “plurality of support points”.

The housing 104 has an opening portion that opens toward a first direction and through which the semiconductor substrate 106 is taken in and out. In a case where the semiconductor substrate 106 is not taken in and out, an opening portion of the housing 104 is closed by the lid 105.

As illustrated in FIG. 2, the partition portion 101 has an extending portion extending in a second direction orthogonal to the first direction, and both end portions in an extending direction of the extending portion are connected (fixed) to the inside of the housing 104 although not illustrated. The partition portion 101 has a protruding portion protruding in a third direction orthogonal to the first direction and the second direction. The partition portion 101 is configured to be capable of accommodating a plurality of the semiconductor substrates 106 in a state in which an outer peripheral portion of a plurality of the semiconductor substrates 106 up to 25 arranged at intervals of 10 mm in the second direction are partitioned by the protruding portion. Note that in the present description, a numerical value such as 10 mm may have a normal error.

As illustrated in FIG. 1, in a case where an opening portion of the housing 104 is closed by the lid 105, an end portion on the opening portion side of the semiconductor substrate 106 accommodated in the partition portion 101 abuts on the lid 105. For this reason, in a case where an opening portion of the housing 104 is closed by the lid 105, a position of the semiconductor substrate 106 in the first direction and the third direction is fixed by the partition portion 101 and the lid 105. Note that, in FIG. 1, the semiconductor substrate 106 is accommodated in the partition portion 101 such that a notch 108 of the semiconductor substrate 106 faces a direction opposite to the opening portion, but the semiconductor substrate 106 may be accommodated in the partition portion 101 such that the notch 108 faces a direction other than the above direction. Further, in a case where a plurality of the semiconductor substrates 106 are accommodated in the partition portion 101, directions in which the notches 108 of a plurality of the semiconductor substrates 106 face do not need to be the same.

A plurality of support points include the upper support point 102 which is a support point closest to an opening portion and the lower support point 103 which is a support point farthest from the opening portion. As illustrated in FIG. 2, a plurality of support points protrude in the second direction from the partition portion 101. An interval between tips of support points adjacent to each other in the second direction is 10 mm, and a distance between support points adjacent to each other in the second direction is less than 10 mm. When the FOUP 100 is arranged in a posture in which the second direction is upward, a plurality of support points support both ends of each of a plurality of the semiconductor substrates 106 accommodated in the partition portion 101 along the second direction.

In a manufacturing process of a semiconductor device such as a power device, the semiconductor substrate 106 is transported from the FOUP 100 to a processing apparatus for processing by a wafer hand (not illustrated). Then, the processing apparatus performs processing for forming a semiconductor element to be a product on an upper surface that is a first main surface of the semiconductor substrate 106 or a lower surface that is a second main surface opposite to the first main surface. Then, the semiconductor substrate 106 is transported from the processing apparatus to the FOUP 100 by a wafer hand.

Note that, in order to suppress damage to a semiconductor element, a wafer hand that transports the semiconductor substrate 106 desirably does not come into contact with a semiconductor element formation region, which is a region where the semiconductor element is formed. In order to realize this, an ineffective region where a semiconductor element is not formed for the wafer hand to come into contact with is preferably provided within 5.0 mm from an outer peripheral portion of the semiconductor substrate 106. Further, in a case where processing of adjusting a shape of an outer peripheral portion of the semiconductor substrate 106 is performed as processing of the lower surface side of the semiconductor substrate 106, a diameter W of a lower portion of the semiconductor substrate 106 may have size of 200 mm or less such as 198 mm (=W−2 mm), for example. For this reason as well, the ineffective region is preferably provided within 5.0 mm from an outer peripheral portion of the semiconductor substrate 106. In a case where such an ineffective region is formed on the semiconductor substrate 106 having the diameter W of 200 mm, a range of a radius of 95 mm (diameter 190 mm) from the center of the semiconductor substrate 106 is an effective region where a semiconductor element is formed. That is, as illustrated in FIG. 1, a diameter W′ of the effective region desirably satisfies W−10 mm<W′<W.

According to the FOUP 100 as described above, size of the housing 104, and further, a distance between a plurality of support points in the second direction and the third direction can be made larger than that of a standard mechanical interface (SMIF). This makes it possible to make a distance between a plurality of the semiconductor substrates 106 accommodated in the partition portion 101 large, and thus, it is possible to transport a maximum of 25 of the semiconductor substrates 106 as one unit while suppressing contact between the semiconductor substrates 106. As a result, manufacturability can be enhanced.

Further, since a plurality of support points provided in the partition portion 101 shift a deflected portion of the semiconductor substrate 106 in a direction opposite to a deflection direction, it is possible to prevent a wafer hand moving in the first direction from unintentionally coming into contact with the deflected portion of the semiconductor substrate 106. Note that in FIG. 2, the semiconductor substrate 106a having a small deflection amount and the semiconductor substrate 106b having a large deflection amount are accommodated in the partition portion 101, but the configuration may be such that one of the semiconductor substrate 106a and the semiconductor substrate 106b is accommodated in the partition portion 101.

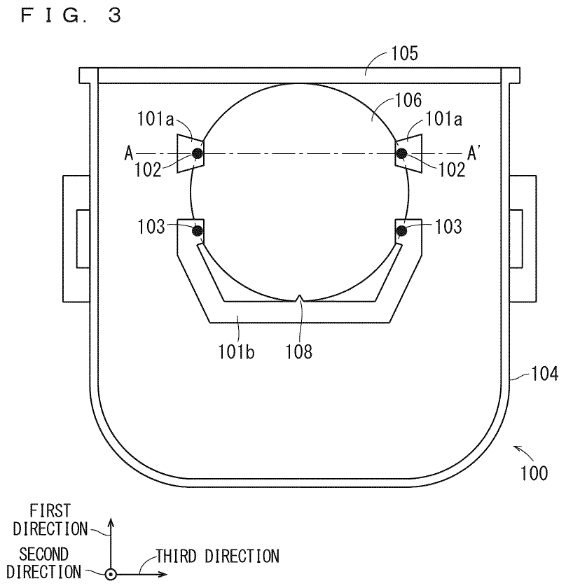

Further, the partition portion 101 of the FOUP 100 described above has a bent shape when viewed from the second direction as illustrated in FIG. 1, but is not limited to this, and may have, for example, a linear shape that is not bent. Further, in FIG. 1, the upper support point 102 and the lower support point 103 are provided on the same partition portion 101, but the present invention is not limited to this. For example, as illustrated in FIG. 3, the partition portion 101 may include a first partition portion 101a and a second partition portion 101b located on the opposite side of an opening portion with respect to the first partition portion 101a. Then, the upper support point 102 and the lower support point 103 may be provided on different ones of the partition portions 101 as in a configuration in which the upper support point 102 protrudes from the first partition portion 101a and the lower support point 103 protrudes from the second partition portion 101b.

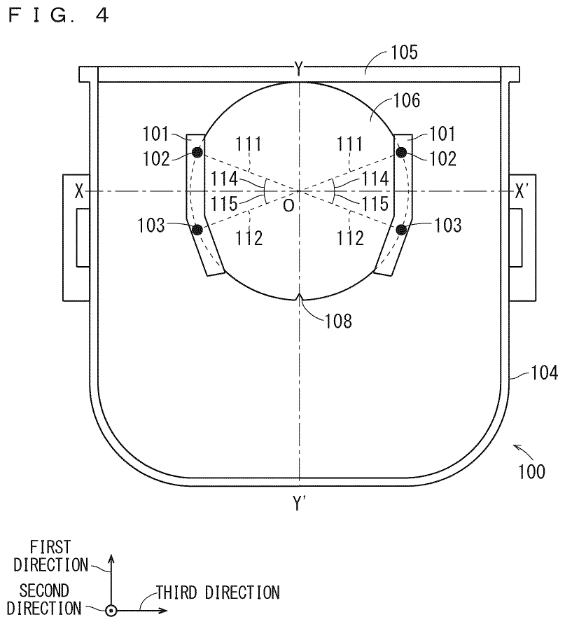

Similarly to FIG. 1, FIG. 4 is a top view illustrating a configuration of the FOUP 100 according to the first preferred embodiment, and illustrates the arrangement of the upper support point 102 and the lower support point 103 viewed from the second direction. FIG. 4 illustrates a center O of the semiconductor substrate 106 accommodated in the partition portion 101, an X-X′ line that is parallel to the third direction and passes through the center O, and a Y-Y′ line that is parallel to the first direction and passes through the center O.

In the first preferred embodiment, an angle 114 formed by a direction 111 from the center O of the semiconductor substrate 106 accommodated in the partition portion 101 toward the upper support point 102 closest to an opening portion among a plurality of support points and the third direction of the X-X′line is 13° or more and 46° or less. Further, an angle 115 formed by a direction 112 from the center O of the semiconductor substrate 106 accommodated in the partition portion 101 toward the lower support point 103 farthest from an opening portion among a plurality of support points and the third direction of the X-X′ line is 13° or more and 46° or less. Although details will be described later, according to such a configuration, it is possible to suppress deflection of the semiconductor substrate 106 accommodated in the FOUP 100.

In the first preferred embodiment, a distance L (see FIG. 2) in the third direction between the upper support points 102 capable of supporting both ends of the semiconductor substrate 106 is larger than W×cos 46° mm and less than W×cos 13° mm. W′ is a diameter of an effective region of the semiconductor substrate 106 (see FIG. 1). Note that although not illustrated, a distance in the third direction between the lower support points 103 capable of supporting both ends of the semiconductor substrate 106 is also larger than W×cos 46° mm and less than W×cos 13° mm.

### Manufacturing Method

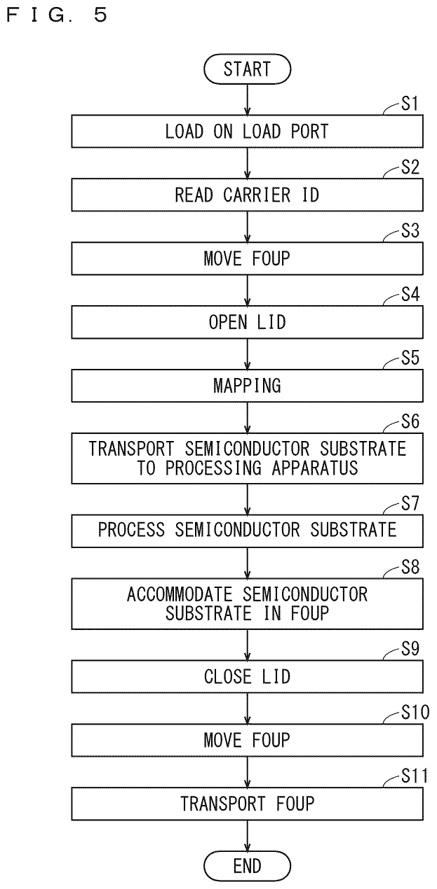

FIG. 5 is a flowchart showing the method of manufacturing a semiconductor device according to the first preferred embodiment. FIG. 5 illustrates a step of accommodating and transporting the semiconductor substrate 106 in the FOUP 100, which is a transport carrier capable of accommodating a maximum of 25 of the semiconductor substrates 106. The step of FIG. 5 is performed at least one of before and after processing described later for forming a semiconductor element on the semiconductor substrate 106.

In Step S1, the FOUP 100 accommodating the semiconductor substrate 106 is transported from an automatic guided vehicle (AGV), an overhead hoist transport (OHT), or the like to a load port and loaded on the load port.

In Step S2, the load port reads a carrier ID attached to the FOUP 100, and in Step S3, the load port moves and causes the FOUP 100 to be connected to a predetermined entrance and exit so that a wafer hand can transport the semiconductor substrate 106 accommodated in the FOUP 100 to a processing apparatus.

In Step S4, the lid 105 of the FOUP 100 is opened, and in Step S5, mapping for measuring a position and the number of the semiconductor substrates 106 accommodated in the FOUP 100 is performed. In Step S6, a wafer hand transports the semiconductor substrate 106 accommodated in the FOUP 100 from the FOUP 100 to the processing apparatus. In Step S7, the processing apparatus performs processing for forming a semiconductor element on the transported semiconductor substrate 106. In Step S8, a wafer hand transports and accommodates the processed semiconductor substrate 106 from the processing apparatus to the FOUP 100. Steps S6 to S8 are usually performed for each of the semiconductor substrates 106 accommodated in the FOUP 100.

In Step S9, the lid 105 of the FOUP 100 is closed, and in Step S10, the load port releases connection between the FOUP 100 and the entrance and exit, and moves the FOUP 100 so that the AGV or the OHT can transport the FOUP 100. In Step S11, the AGV or the OHT transports the FOUP 100.

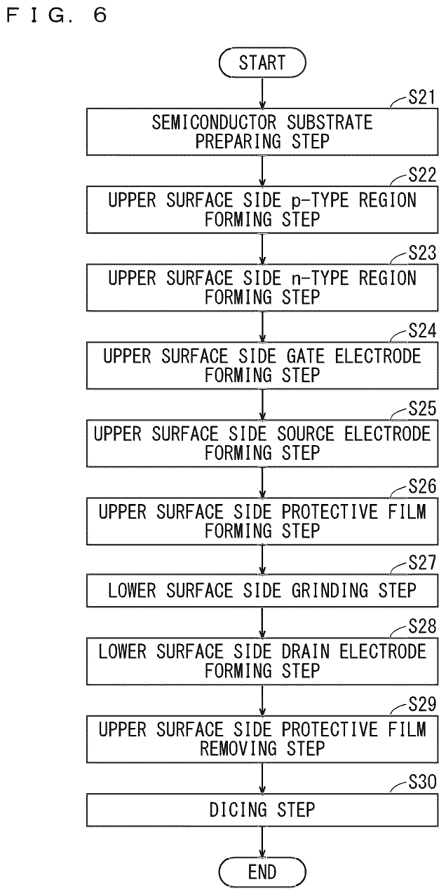

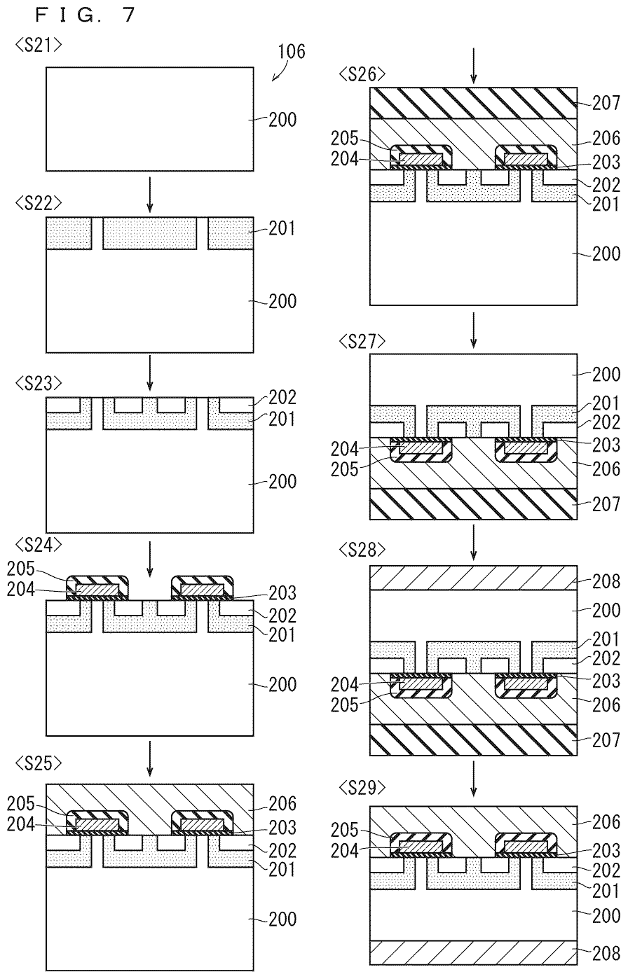

FIG. 6 is a flowchart illustrating the method of manufacturing a semiconductor device according to the first preferred embodiment, and illustrates an example of processing for forming a semiconductor element on the semiconductor substrate 106. FIG. 7 is a cross-sectional view of the semiconductor substrate 106 illustrating the method of manufacturing a semiconductor device according to the first preferred embodiment. Hereinafter, a method of manufacturing an active region of a planar type metal oxide semiconductor field effect transistor (MOSFET) which is a type of semiconductor device will be described. However, the semiconductor device may be a trench type MOSFET, an insulated gate bipolar transistor (IGBT), a reverse conducting-IGBT (RC-IGBT), a Schottky barrier diode (SBD), a PN junction diode (PND), or the like. Note that in the first preferred embodiment, the active region is a semiconductor element formation region described above.

Processing for forming a semiconductor element on the semiconductor substrate 106 includes a semiconductor substrate preparing step (Step S21), an upper surface side p-type region forming step (Step S22), an upper surface side n-type region forming step (Step S23), an upper surface side gate electrode forming step (Step S24), an upper surface side source electrode forming step (Step S25), an upper surface side protective film forming step (Step S26), a lower surface side grinding step (Step S27), a lower surface side drain electrode forming step (Step S28), an upper surface side protective film removing step (Step S29), and a dicing step (Step S30).

Note that processing performed before or after transport of the FOUP 100 does not need to include all the above steps. For example, in a case where it is necessary to transfer the semiconductor substrate 106 to a dedicated carrier in the dicing step in Step S30, the dicing step in Step S30 does not need to be included in processing performed before or after the FOUP 100 is transported. Hereinafter, a step in FIGS. 6 and 7 will be described.

In the semiconductor substrate preparing step (Step S21), a plurality of the semiconductor substrates 106 to be an n-type drift layer 200 in FIG. 7 are prepared. In this step, a semiconductor substrate made from silicon carbide and having the diameter W of 200 mm or more is prepared. In description of the manufacturing process below, for convenience, a configuration in which other semiconductor layers and electrodes are formed in the n-type drift layer 200 is also referred to as the semiconductor substrate 106.

In the upper surface side p-type region forming step (Step S22), an ion implantation step and a heating step are performed. In the ion implantation step, a donor is ion-implanted into the upper surface side of the semiconductor substrate 106. As the donor, for example, boron and aluminum are used. In the heating step, the semiconductor substrate 106 is heated to electrically activate the donor. By the above, a p-type region 201 is formed.

In the upper surface side n-type region forming step (Step S23), an exposure step, an etching step, an ion implantation step, and a heating step are performed. In the exposure step, photoresist having uniform thickness is applied to the upper surface side of the semiconductor substrate 106. The photoresist may be either photosensitive or non-photosensitive. Then, a photoresist film is selectively exposed from the upper surface side of the semiconductor substrate 106 by using a photomask. In the etching step, the photoresist film is selectively removed by performing dry etching or wet etching on the photoresist film.

In the ion implantation step, an acceptor is ion-implanted into an upper surface of the p-type region 201 exposed from the photoresist film, and then a remaining photoresist film is removed. As the acceptor, for example, nitrogen, phosphorus, or the like is used. In the heating step, the semiconductor substrate 106 is heated to electrically activate an acceptor ion. By the above, an n-type region 202 is formed. As described above, by performing the exposure step and the etching step, a patterned impurity region and film can be formed, and an impurity region and film can be selectively formed on the semiconductor substrate 106. Hereinafter, for convenience of description, description of removal of a remaining photoresist film, the exposure step, and the etching step may be omitted. A semiconductor element is formed on a semiconductor substrate by performing the ion implantation step and the heating step.

In the upper face side gate electrode forming step (Step S24), an oxide film forming step, a polysilicon film forming step, an exposure step, an etching step, and an oxide film forming step are performed. In the oxide film forming step, an oxide film 203 is formed on the p-type region 201 and the n-type region 202 by heating the semiconductor substrate 106 in atmosphere containing oxygen. In the polysilicon film forming step, a polysilicon film doped with n-type or p-type impurities is deposited by chemical vapor deposition (CVD) or the like. In the exposure step, photoresist having uniform thickness is applied to the upper surface side of the semiconductor substrate 106. The photoresist may be either photosensitive or non-photosensitive. Then, a photoresist film is selectively exposed from the upper surface side of the semiconductor substrate 106 by using a photomask.

In the etching step, the photoresist film is selectively removed by performing dry etching or wet etching on the photoresist film. Then, a polysilicon film exposed from the photoresist film is removed to form a gate electrode 204 facing an upper portion of the p-type region 201 with the oxide film 203 interposed between them. In the oxide film forming step, an oxide film 205 covering the gate electrode 204 is formed by heating the semiconductor substrate 106 in atmosphere containing oxygen or performing CVD or the like. After the above, the oxide films 203 and 205 between the gate electrodes 204 are removed to expose the n-type region 202.

In the upper surface side source electrode forming step (Step S25), a source electrode 206 connected to the n-type region 202 is formed on the upper surface side of the semiconductor substrate 106 by a sputtering apparatus or the like. A material of the source electrode 206 is, for example, nickel. In order to reduce contact resistance of the source electrode 206, the source electrode 206 may be formed after heat treatment and a silicide process are performed on an upper surface of the n-type region 202.

In the upper surface side protective film forming step (Step S26), a protective film 207 is formed on the source electrode 206, that is, on the upper surface side of the semiconductor substrate 106. As the protective film 207, for example, tape, a glass plate, or the like is used, but one having small thickness is more desirable from the viewpoint of cost. In the steps so far, since thickness of the semiconductor substrate 106 is sufficiently large, deflection of the semiconductor substrate 106 in the FOUP 100 is about a fraction of a millimeter.

In the lower surface side grinding step (Step S27), front and back surfaces of the semiconductor substrate 106 are reversed, the protective film 207 on the upper surface side of the semiconductor substrate 106 is adsorbed on a stage of a grinding apparatus, and the lower surface side of the semiconductor substrate 106 is ground so that the n-type drift layer 200 has thickness of several 100 μm. Note that, for example, Japanese Patent No. 6194210 proposes a grinding method for leaving a rim in order to suppress deflection of the semiconductor substrate 106. However, in a case where the semiconductor substrate 106 is made from a hard brittle material such as SiC, it is desirable to grind the semiconductor substrate 106 so that thickness becomes uniform as a whole in order to suppress abrasion of a grindstone, occurrence of cracking of the semiconductor substrate 106, and the like. Since a damaged layer remains on a surface layer on the lower surface side of the semiconductor substrate 106 after grinding, the damaged layer may be removed by etching.

The semiconductor substrate 106 after grinding is easily deformed, and as in the semiconductor substrate 106a accommodated in the FOUP 100 of FIG. 2, deflection in the second direction due to its own weight becomes maximum at the center.

In the lower surface side drain electrode forming step (Step S28), as illustrated in FIG. 7, a drain electrode 208 is formed on the lower surface side of the semiconductor substrate 106 by using a sputtering apparatus or the like. A material of the drain electrode 208 is, for example, nickel, titanium, or the like. In order to reduce contact resistance of the drain electrode 208, the drain electrode 208 may be formed after heat treatment and a silicide process are performed on a lower surface of the n-type drift layer 200 (corresponding to an upper surface in Step S28 in FIG. 7). For the heat treatment, for example, a laser is used.

In the upper surface side protective film removing step (Step S29), front and back surfaces of the semiconductor substrate 106 are reversed, and the protective film 207 provided on the upper surface side of the semiconductor substrate 106 is removed. In a case where the protective film 207 is tape, the tape is physically peeled off the semiconductor substrate 106, and tape adhesive residue is removed by wet etching or the like. Note that in a case where heat-resistant temperature of the protective film 207 is lower than rising temperature in the lower surface side drain electrode forming step (Step S28), the lower surface side drain electrode forming step (Step S28) and the upper surface side protective film removing step (Step S29) are preferably performed in the reversed order.

In the dicing step (Step S30), each semiconductor element is cut out from the semiconductor substrate 106. Through the above steps, a semiconductor element is manufactured as a semiconductor device. However, a semiconductor device as a target of the method of manufacturing a semiconductor device may be a semiconductor module in which a semiconductor element is provided with, for example, a wire or the like and then sealed with sealing resin, or may be a device in which the semiconductor module is further incorporated.

### Summary of First Preferred Embodiment

According to the method of manufacturing a semiconductor device according to the first preferred embodiment as described above, the semiconductor substrate 106 is accommodated and transported in the FOUP 100 that can accommodate a maximum of 25 of the semiconductor substrates 106 having the diameter W of 200 mm or more made from silicon carbide. According to such a configuration, it is possible to transport a maximum of 25 of the semiconductor substrates 106 as one unit while suppressing contact between the semiconductor substrates 106, and thus, it is possible to enhance manufacturability.

The above effect is particularly effective in a case where a maximum of 25 of the semiconductor substrates 106 are transported after the lower surface side grinding step (Step S27) in which a deflection amount of the semiconductor substrates 106 is large. Further, in the upper surface side protective film forming step (Step S26), the above effect is particularly effective in a case where tape that increases a deflection amount of the semiconductor substrate 106 is used as the protective film 207. Further, in a case where a glass plate is used as the protective film 207 in the upper surface side protective film forming step (Step S26), a deflection amount of the semiconductor substrate 106 can be reduced.

Further, in the first preferred embodiment, since a plurality of support points are provided in the partition portion 101, it is possible to prevent a wafer hand from unintentionally coming into contact with a deflected portion of the semiconductor substrate 106.

Further, in the first preferred embodiment, the angle 114 formed by the direction 111 from the center O of the semiconductor substrate 106 accommodated in the partition portion 101 toward the upper support point 102 closest to an opening portion among a plurality of support points and the third direction of the X-X′line is 13° or more and 46° or less. Further, an angle 115 formed by a direction 112 from the center O of the semiconductor substrate 106 accommodated in the partition portion 101 toward the lower support point 103 farthest from an opening portion among a plurality of support points and the third direction of the X-X′ line is 13° or more and 46° or less. Hereinafter, an effect of this configuration will be described.

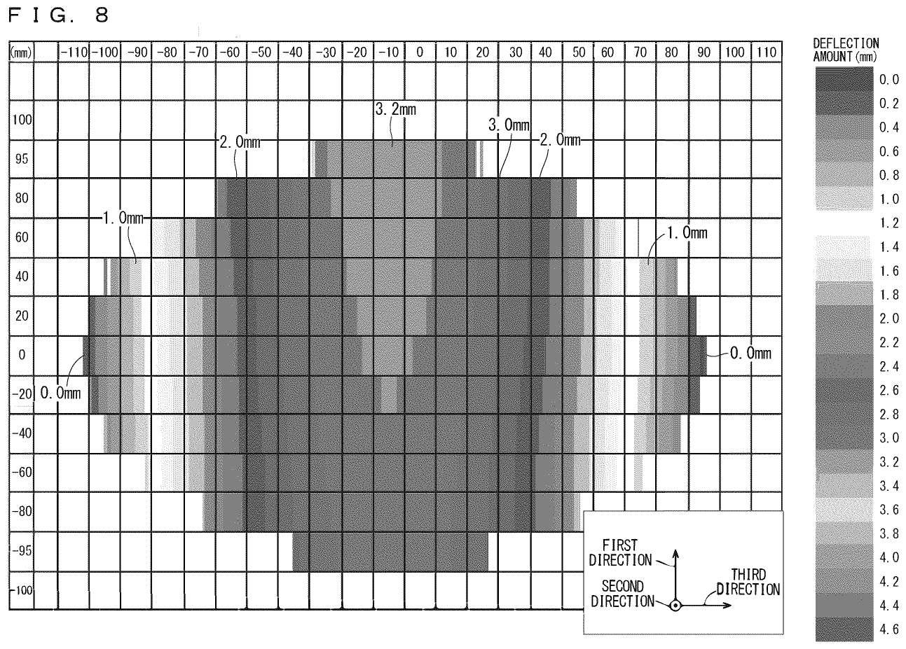

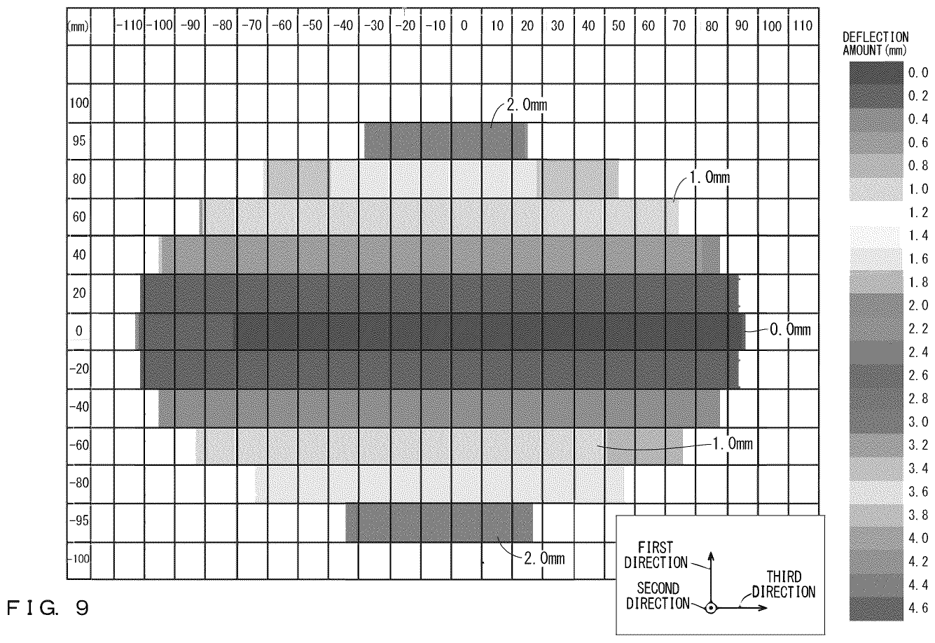

FIGS. 8 and 9 are two-dimensional maps illustrating a deflection amount of the semiconductor substrate 106 in a case where the semiconductor substrate 106 in the lower surface side drain electrode forming step (Step S28) is supported in the FOUP 100 at a plurality of support points having the angles 114 and 115 of 30°. FIG. 8 is a two-dimensional map when the semiconductor substrate 106 is accommodated in the partition portion 101 such that the upper surface side faces TOP (the upper side in FIG. 2). FIG. 9 is a two-dimensional map when the semiconductor substrate 106 is accommodated in the partition portion 101 such that the upper surface side faces BOTTOM (the lower side in FIG. 2). FIG. 8 shows that a deflection amount has a maximum value (3.2 mm) at a center portion parallel to the first direction in the semiconductor substrate 106. On the other hand, FIG. 9 shows that a deflection amount has a maximum value (2.0 mm) at both end portions parallel to the third direction in the semiconductor substrate 106.

FIG. 10 is a diagram illustrating a relationship between the angles 114 and 115 of the upper support point 102 and the lower support point 103 in FIG. 4 and a maximum deflection amount of the semiconductor substrate 106 accommodated in the FOUP 100. A plot 301 shows a maximum deflection amount (hereinafter, also referred to as a “TOP direction maximum deflection amount”) when the semiconductor substrate 106 is accommodated such that an upper surface faces TOP as in a deflection amount of FIG. 8. A plot 302 shows a maximum deflection amount (hereinafter, also referred to as a “BOTTOM direction maximum deflection amount”) when the semiconductor substrate 106 is accommodated such that an upper surface faces BOTTOM as in a deflection amount of FIG. 9. As can be seen from the plots 301 and 302, the TOP direction maximum deflection amount is larger than the BOTTOM direction maximum deflection amount.

Here, in the description of steps S27 to S29, front and back surfaces of the semiconductor substrate 106 are reversed, but when such reversal is performed, throughput is reduced. In view of the above, hereinafter, a case where the semiconductor substrate 106 is processed and transported without reversal of the semiconductor substrate 106 in Steps S27 to S29 will be assumed. In this case, since the semiconductor substrate 106 is accommodated in the partition portion 101 such that the upper surface side faces TOP (the upper side in FIG. 2), the TOP direction maximum deflection amount is assumed.

In order for a wafer hand having thickness of 5.0 mm in the second direction to move to a mounting position of the semiconductor substrate 106 without coming into contact with the semiconductor substrate 106 and the partition portion 101, a gap of 1.0 mm is required between the wafer hand and the semiconductor substrate 106. Considering that the semiconductor substrates 106a and 106b are accommodated in the FOUP 100 as illustrated in FIG. 2, since an interval between tips of support points adjacent in the second direction is 10 mm, a deflection amount of the semiconductor substrate 106 can be allowed up to 4.0 mm.

In FIG. 10, from an intersection of the plot 301 and the TOP direction maximum deflection amount of 4.0 mm, the angles 114 and 115 can be allowed up to 13°. On the other hand, when the angle 114 (angle 115) in FIG. 4 increases, a distance in the third direction between the upper support points 102 (between the lower support points 103) decreases. Assuming that width of a wafer hand in the third direction is 170 mm or less, the angles 114 and 115 can be allowed up to 46°. In the first preferred embodiment, since the angles 114 and 115 of the upper support point 102 and the lower support point 103 is 13° or more and 46° or less, a maximum deflection amount of the semiconductor substrate 106 can be appropriately suppressed.

### Second Preferred Embodiment

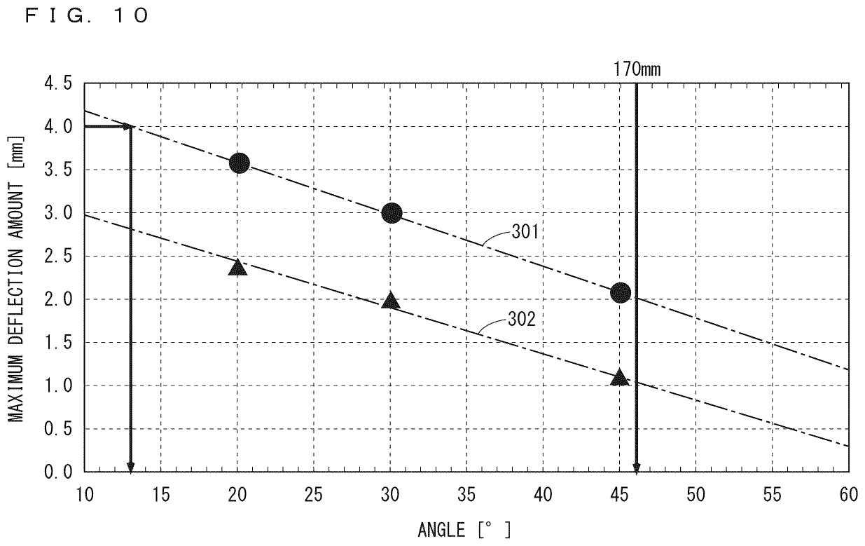

FIG. 11 is a cross-sectional view illustrating the upper support point 102 and the lower support point 103 according to the second preferred embodiment as viewed from the third direction. In the second preferred embodiment, as illustrated in FIG. 11, the upper support point 102 is higher than the lower support point 103 by, for example, 0.1 mm in the second direction. According to such a configuration, it is possible to suppress deflection of the semiconductor substrate 106 in which the TOP direction maximum deflection amount exists on the opening portion side of the FOUP 100 as illustrated in FIG. 8.

### Third Preferred Embodiment

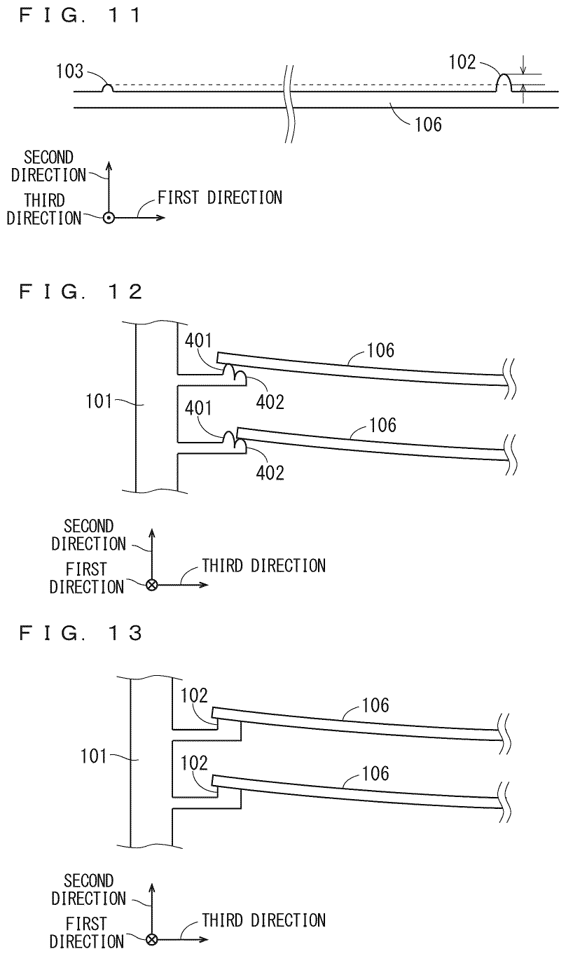

FIG. 12 is a cross-sectional view illustrating a plurality of support points according to a third preferred embodiment as viewed from the first direction. Although not illustrated, a configuration obtained by horizontally reversing the configuration of FIG. 12 is provided on the right side of FIG. 12. In the third preferred embodiment, when viewed from the first direction, a tip of a first set of support points 401 among a plurality of support points is higher than a tip of a second set of support points 402 further on the inner side than the first set of the support points 401 among a plurality of support points. According to such a configuration, the semiconductor substrates 106 having the different diameters W can be accommodated in the same FOUP 100, and deflection of the semiconductor substrates 106 having the different diameters W can be suppressed.

### Fourth Preferred Embodiment

FIG. 13 is a cross-sectional view illustrating the upper support point 102 according to the fourth preferred embodiment as viewed from the first direction. In the fourth preferred embodiment, as illustrated in FIG. 12, the upper support point 102 is in surface contact with the semiconductor substrate 106 accommodated in the partition portion 101. Further, although not illustrated, the lower support point 103 is also in surface contact with the semiconductor substrate 106 accommodated in the partition portion 101. According to such a configuration, as compared with a configuration in which the upper support point 102 and the lower support point 103 are in point contact with the semiconductor substrate 106, stress on the semiconductor substrate 106 can be reduced, and deflection of the semiconductor substrate 106 can be suppressed.

### Variation

In FIGS. 1, 2, 4, 12, and 13, the partition portion 101 may be detachable. According to such a configuration, when the partition portion 101 is replaced with a partition portion for supporting a semiconductor substrate having the diameter W of 300 mm, a semiconductor substrate having the diameter W of 300 mm can be accommodated in the same housing 104. Therefore, the number of the FOUPs 100 to be prepared can be reduced, and capacity of a stocker for storing the FOUPs 100 can be reduced.

Note that the preferred embodiments and the variations can be freely combined, and the preferred embodiments and the variations can be appropriately modified or omitted.

Hereinafter, various aspects of the present disclosure will be collectively described as an appendix.

### Appendix 1

A method of manufacturing a semiconductor device, the method including:
a step of preparing a semiconductor substrate made from silicon carbide and having a diameter W of 200 mm or more;
a step of performing processing for forming a semiconductor element on the semiconductor substrate; and
a step of accommodating and transporting the semiconductor substrate in a FOUP that is a transport carrier capable of accommodating a maximum of 25 of the semiconductor substrates at least one of before and after the processing.

### Appendix 2

The method of manufacturing a semiconductor device according to Appendix 1, in which
the processing includes at least one of:
a step of forming a plurality of impurity regions in the semiconductor substrate;
a step of forming a protective film on a first main surface of the semiconductor substrate; and
a step of grinding a second main surface opposite to the first main surface of the semiconductor substrate after the protective film is formed.

### Appendix 3

The method of manufacturing a semiconductor device according to Appendix 2, in which
the protective film is a glass plate.

### Appendix 4

The method of manufacturing a semiconductor device according to Appendix 2, in which
the protective film is tape.

### Appendix 5

The method of manufacturing a semiconductor device according to any one of Appendices 1 to 4, in which
the FOUP includes:
a housing having an opening portion that opens toward a first direction and through which the semiconductor substrate is taken in and out;
a partition portion connected to an inside of the housing and capable of partitioning and accommodating an outer peripheral portion of a plurality of the semiconductor substrates up to 25 arranged at an interval of 10 mm in a second direction orthogonal to the first direction; and
a plurality of support points protruding from the partition portion in the second direction and capable of supporting each of a plurality of the semiconductor substrates accommodated in the partition portion along the second direction,
when viewed from the second direction, an angle formed by a direction from a center of the semiconductor substrate accommodated in the partition portion toward the support point closest to the opening portion among a plurality of the support points and a third direction orthogonal to the first direction and the second direction is 13° or more and 46° or less,
W−10 mm<W′<W holds for a diameter W′ of an effective region of the semiconductor substrate, and
a distance in the third direction between support points capable of supporting the semiconductor substrate among a plurality of the support points is larger than W×cos 46° mm and less than W×cos 13° mm.

### Appendix 6

The method of manufacturing a semiconductor device according to Appendix 5, in which
the partition portion includes a first partition portion and a second partition portion located on a side opposite to the opening portion with respect to the first partition portion, and
the support point closest to the opening portion among a plurality of the support points protrudes from the first partition portion, and
the support point farthest from the opening portion among a plurality of the support points protrudes from the second partition portion.

### Appendix 7

The method of manufacturing a semiconductor device according to Appendix 5 or 6, in which
an angle formed by the third direction and a direction from a center of the semiconductor substrate accommodated in the partition portion toward the support point farthest from the opening portion among a plurality of the support points when viewed from the second direction is 13° or more and 46° or less.

### Appendix 8

The method of manufacturing a semiconductor device according to any one of Appendices 5 to 7, in which
a support point closest to the opening portion among a plurality of the support points is higher in the second direction than the support point farthest from the opening portion among the plurality of support points.

### Appendix 9

The method of manufacturing a semiconductor device according to any one of Appendices 5 to 8, in which
a tip of a first set of the support points among a plurality of the support points is higher than a tip of a second set of the support points further on an inner side than the first set of the support points among a plurality of the support points when viewed from the first direction.

### Appendix 10

The method of manufacturing a semiconductor device according to any one of Appendices 5 to 9, in which
a plurality of the support points are in surface contact with the semiconductor substrate accommodated in the partition portion.

### Appendix 11

The method of manufacturing a semiconductor device according to any one of Appendices 5 to 10, in which
the partition portion is replaceable.

While the disclosure has been shown and described in detail, the foregoing description is in all aspects illustrative and not restrictive. It is therefore understood that numerous modifications and variations can be devised.

What is claimed is:

1. A method of manufacturing a semiconductor device, the method comprising:
a step of preparing a semiconductor substrate made from silicon carbide and having a diameter W of 200 mm or more;
a step of performing processing for forming a semiconductor element on the semiconductor substrate; and
a step of accommodating and transporting the semiconductor substrate in a FOUP that is a transport carrier capable of accommodating a maximum of 25 of the semiconductor substrates at least one of before and after the processing.

2. The method of manufacturing a semiconductor device according to claim 1, wherein
the processing includes at least one of:
a step of forming a plurality of impurity regions in the semiconductor substrate;
a step of forming a protective film on a first main surface of the semiconductor substrate; and
a step of grinding a second main surface opposite to the first main surface of the semiconductor substrate after the protective film is formed.

3. The method of manufacturing a semiconductor device according to claim 2, wherein
the protective film is a glass plate.

4. The method of manufacturing a semiconductor device according to claim 2, wherein
the protective film is tape.

5. The method of manufacturing a semiconductor device according to claim 1, wherein
the FOUP includes:
a housing having an opening portion that opens toward a first direction and through which the semiconductor substrate is taken in and out;
a partition portion connected to an inside of the housing and capable of partitioning and accommodating an outer peripheral portion of a plurality of the semiconductor substrates up to 25 arranged at an interval of 10 mm in a second direction orthogonal to the first direction; and
a plurality of support points protruding from the partition portion in the second direction and capable of supporting each of the plurality of semiconductor substrates accommodated in the partition portion along the second direction,
when viewed from the second direction, an angle formed by a direction from a center of the semiconductor substrate accommodated in the partition portion toward the support point closest to the opening portion among the plurality of support points and a third direction orthogonal to the first direction and the second direction is 13° or more and 46° or less,
W−10 mm<W′<W holds for a diameter W′ of an effective region of the semiconductor substrate, and a distance in the third direction between support points capable of supporting the semiconductor substrate among the plurality of support points is larger than W×cos 46° mm and less than W×cos 13° mm.

6. The method of manufacturing a semiconductor device according to claim 5, wherein
the partition portion includes a first partition portion and a second partition portion located on a side opposite to the opening portion with respect to the first partition portion, and
the support point closest to the opening portion among the plurality of support points protrudes from the first partition portion, and
the support point farthest from the opening portion among the plurality of support points protrudes from the second partition portion.

7. The method of manufacturing a semiconductor device according to claim 5, wherein
an angle formed by the third direction and a direction from a center of the semiconductor substrate accommodated in the partition portion toward the support point farthest from the opening portion among the plurality of support points when viewed from the second direction is 13° or more and 46° or less.

8. The method of manufacturing a semiconductor device according to claim 5, wherein
a support point closest to the opening portion among the plurality of support points is higher in the second direction than the support point farthest from the opening portion among the plurality of support points.

9. The method of manufacturing a semiconductor device according to claim 5, wherein
a tip of a first set of the support points among the plurality of support points is higher than a tip of a second set of the support points further on an inner side than the first set of the support points among the plurality of support points when viewed from the first direction.

10. The method of manufacturing a semiconductor device according to claim 5, wherein
the plurality of support points are in surface contact with the semiconductor substrate accommodated in the partition portion.

11. The method of manufacturing a semiconductor device according to claim 5, wherein
the partition portion is replaceable.
